(19) United States
(12) Patent Application Publication
(10) Pub. No.: US 2021/0399152 A1
(43) Pub. Date: Dec. 23, 2021

(54) GLASS BRICK WITH LUMINESCENT SOLAR CONCENTRATOR FOR PRODUCTION OF ELECTRICAL ENERGY

(71) Applicants: UNIVERSITA' DEGLI STUDI DI MILANO - BICOCCA, Miliano (IT); GLASS TO POWER S.P.A., Rovereto (TN) (IT)

(72) Inventors: Francesco MEINARDI, Lecco (IT); Sergio BROVELL, Milano (IT); Francesco BRUNI, Cernusco sul Naviglio (MI) (IT); Marina GANDINI, Milano (IT); Emillo SASSONE CORSI, Rocca Priora (RM) (IT); Graziella GARIANO, San Martino Siccomario (PV) (IT); Chiara CAPITANI, Voghera (PV) (IT)

(73) Assignees: UNIVERSITA' DEGLI STUDI DI MILANO - BICOCCA, Milano (IT); GLASS TO POWER S.P.A., Rovereto (TN) (IT)

(21) Appl. No.: 17/289,512

(22) PCT Filed: Oct. 28, 2019
(86) PCT No.: PCT/IB2019/059232

§ 371 Date: Apr. 28, 2021

(30) Foreign Application Priority Data
Oct. 31, 2018 (IT) 102018000009951

(51) Int. Cl. H01L 31/048; E04C 1/42; E04C 1/39

(52) U.S. Cl. CPC H01L 31/0488; H01L 31/055; E04C 1/397; E04C 1/42

(57) ABSTRACT

A glass brick having a luminescent solar concentrator inserted inside it, between the preformed glass portions which constitute the body of the glass brick is provided.

The subject of the present invention is a glass brick according to the preamble of the main claim.

As is known, a glass brick is a building material used to produce walls or (perimeter or internal) sections of walls, partitions, skylights, or flooring, in order to create lighting environments. The composition of a plurality of glass bricks is commonly defined as a glass block.

A glass brick is typically composed of glass, concrete and steel, and comprises two preformed parts (which for the sake of simplicity will be indicated as being made of glass) joined to one another integrally by an appropriate sealant. The product permits creation of a vacuum space between said parts which define the outer faces of the glass brick. The product thus has optimum thermal and acoustic insulation properties, and can be designed to control the intensity and diffusion of the light, the thermal insulation, the resistance to fire, resistance to being walked on or the like, in relation to specific uses. In this conventional form, a glass brick or glass block structure dissipates in itself the energy of the solar radiation which strikes it.

Luminescent solar concentrators are also known which make it possible to transform the solar radiation with which they are supplied, into electrical energy.

As is known, luminescent solar concentrators are composed of a glass or plastics waveguide defining the body of the concentrator, which waveguide is coated or doped with highly emissive components known as fluorophores. The direct and/or diffused sunlight is absorbed by these fluorophores, and is re-emitted with a greater wavelength. The luminescence thus generated is propagated by means of total internal reflection as far as the edges of the waveguide, and at these edges it is absorbed by photovoltaic cells which are coupled to the perimeter of this concentrator, and converted into electrical energy.

By selecting appropriately the concentration of fluorophores in the waveguide and their optical properties, it is possible to produce coloured or colourless solar concentrators with different levels of transparency and an arbitrary form, which concentrators can easily be integrated architecturally.

WO2012/147041 describes a glass brick for use in the production of buildings comprising a main body made of transparent material and at least one photovoltaic cell which is placed in the interior of the main body and can generate electricity.

The photovoltaic cell, which is however different from a solar concentrator, is supported by a corresponding element, the edges of which are directly secured internally on said main body.

The objective of the present invention is to provide a glass brick which, as well as the characteristics of a conventional glass brick, such as, for example, thermal-acoustic insulation and regulation of brightness, has the possibility of transferring the solar radiation to which it is subjected into electrical energy, thus becoming a photovoltaic glass brick.

Another objective is to provide a photovoltaic glass brick of the aforementioned type wherein the electrical energy generated can be transferred from one glass brick to another, and collected at the sides of the wall constituted by the glass bricks themselves.

Another objective is to provide a photovoltaic glass brick of the aforementioned type wherein the electrical energy generated can be used to supply power to batteries or delivered to the electrical mains supply of the building or structure in which the glass brick is integrated, individually or in the form of a glass block composition.

A further objective is to provide a photovoltaic glass brick of the aforementioned type which has substantial structural stability in use.

Another objective is to provide a photovoltaic glass brick of the aforementioned type which can be used as a source of supply of power to electrical and/or electronic devices, such as antitheft devices, a Wi-Fi repeater, lighting elements or the like, which devices thus do not need to be supplied with power from the electrical mains of the building in which the glass brick is integrated.

These objectives and others, which will become apparent to persons skilled in the art, are achieved by a glass brick according to the main claim.

For better understanding of the present invention, purely by way of non-limiting indication, the following drawings are appended, in which:

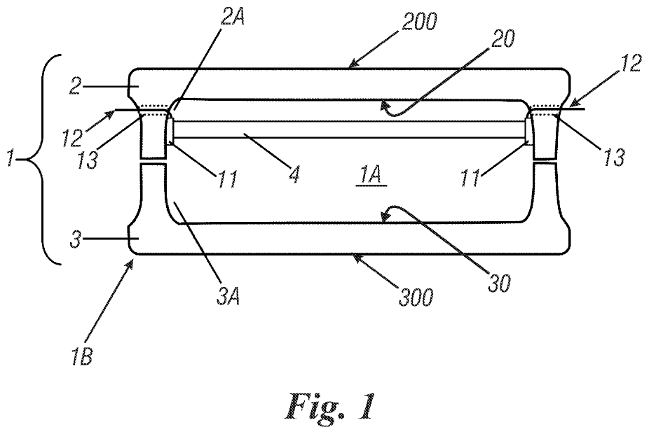

FIG. 1 shows a lateral view in transverse cross-section of a glass brick according to the invention;

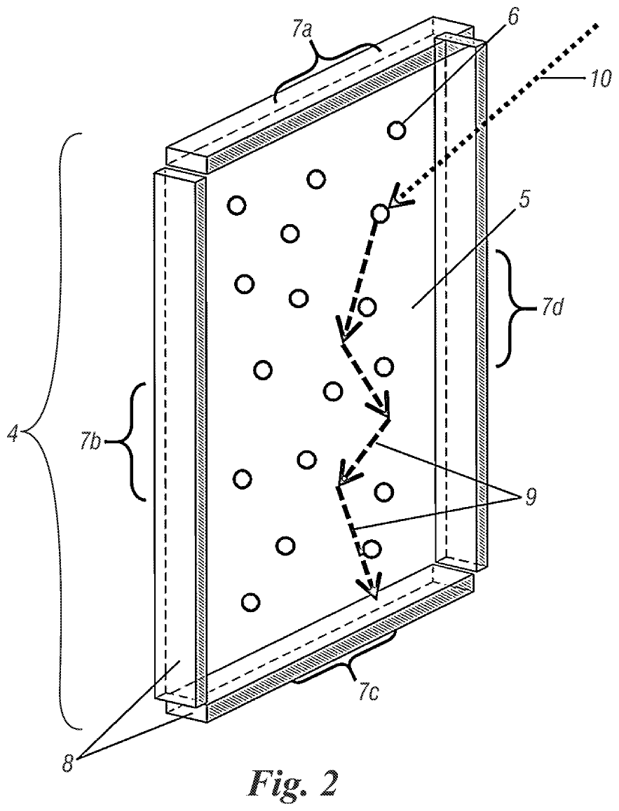

FIG. 2 shows a view in perspective of an example of a luminescent solar concentrator which can be used in the glass brick in FIG. 1;

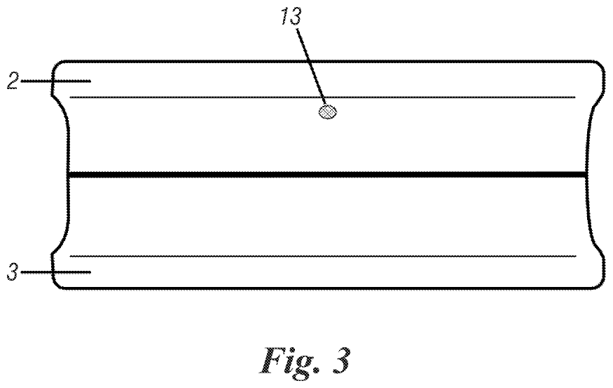

FIG. 3 shows a lateral view of the glass brick in FIG. 1;

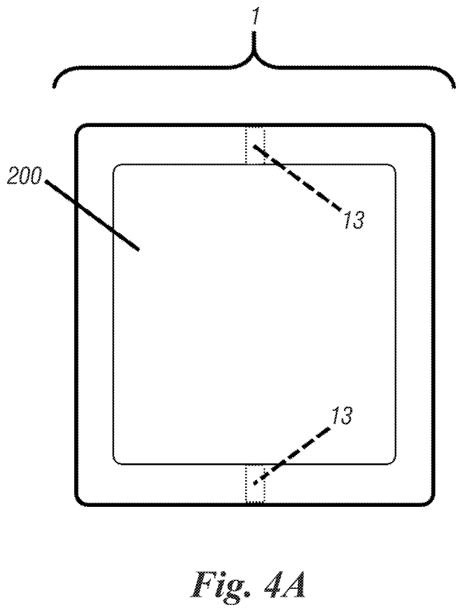

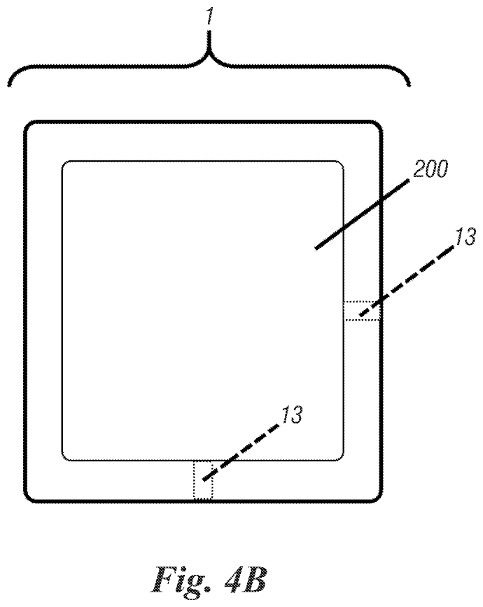

FIGS. 4A and 4B show two frontal views of different possible configurations of glass bricks;

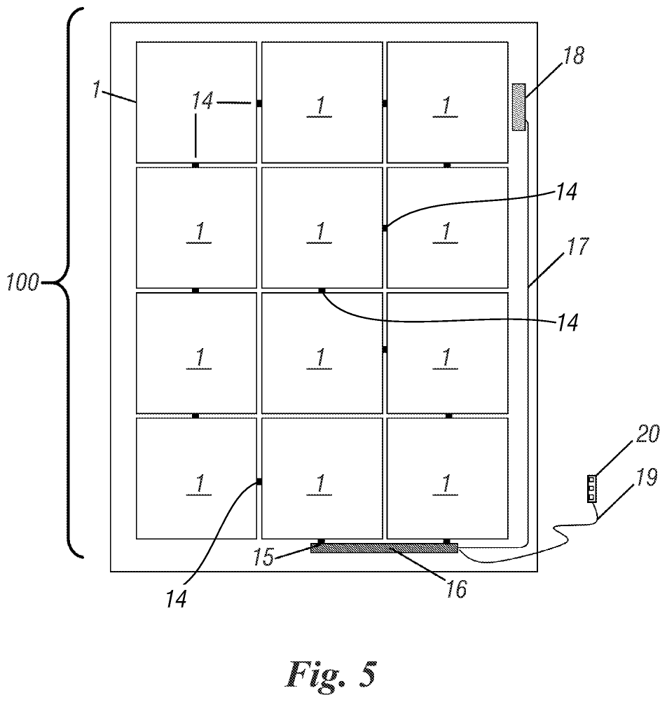

FIG. 5 shows a glass block wall obtained by use of glass bricks such as the one shown in FIG. 1.

With reference to said figures, a glass brick, which hereinafter will be defined as a “photovoltaic glass brick”, is indicated as 1, and comprises two preformed portions 2 and 3, obtained by means of methods which in themselves are known, and which bricks are connected to one another in any known manner. Between these portions 2 and 3, there is present a cavity 1A defined by recesses 2A and 3A which are present in a corresponding face 20 or 30 (which is inner relative to the cavity 1A) of each portion 2 and 3. These cavities comprise an outer face 200 and 300 respectively, forming the free faces of the glass brick 1. The preformed portions 2 and 3, which define a body 1B of the glass brick, will be indicated as glass portions.

Between said portions, in the cavity 1A in the glass brick, there is present an inner panel 4 defined by a luminescent solar concentrator, of a type which in itself is known. This panel or concentrator 4 can be either in the form of a solid plate (such as the one in the figures) or in the form of a film which is coupled to a transparent support (for example a plastics material), described in greater detail in FIG. 2.

The luminescent solar concentrator (or LSC) 4 is connected to the interior of one of the two portions 2, 3 of the photovoltaic glass brick 1, for example in the recess 2A in the portion 2, thanks to spacer units 11. These spacer units are secured on the portion 2 by any known means, for example by means of an adhesive. The spacer units 11 permit stability in the positioning of the luminescent solar concentrator 4, these units 11 being associated perimetrically with at least two sides of said concentrator. In addition, during use of the invention, when the glass brick is subjected to solar radiation, the spacer units 11 can accept the thermal expansions or contractions typical of solar concentrators without affecting the operation thereof, and without having a negative effect on the structural stability of the glass brick.

In addition, each spacer unit 11 permits electrical contact between the luminescent solar concentrator 4 and a known external circuit (not shown in the figures for the sake of simplicity), for the extraction of the electrical energy by means of various solutions, including sliding contacts or through-holes (as described hereinafter).

By way of example, FIG. 2 shows in greater detail a representation of the luminescent solar concentrator 4. The luminescent solar concentrator comprises a main body 5 made of glass or of plastics material, in which there are present emissive substances (which by way of example are shown as elements 6, clearly identifiable in the interior of the body 5). At the edges 7a, 7b, 7c, 7d of the body 5, there are present known photovoltaic cells 8 which can collect the luminous radiation 9 emitted by the emissive substances 6 present in the LSC, after the absorption by the substances of incident solar radiation 10. These photovoltaic cells 8 are coupled optically to the body 5 of the LSC 4 in a known manner, and are connected to one another (according to conventional methods) in order to transfer the electrical energy produced by the luminescent solar concentrator to one of the sides thereof. This energy is extracted from the luminescent solar concentrator by means of appropriate cables or connectors 12 which are inserted in through-holes 13 provided inside the photovoltaic glass brick 1, in one of the two glass portions 2 or 3. By this means, the electrical energy produced by the solar concentrator reaches the outer perimeter of the photovoltaic glass brick 1.

By way of non-limiting example, in FIG. 3, a through-hole 13 is provided in the centre of a side of the portion 2 of the photovoltaic glass brick. However, in addition to the configuration with a single through-hole, it is possible to obtain different configurations, as shown by way of non-limiting example in FIGS. 4A and 4B. These figures show the configurations of a “linear” or “angular” type, wherein the through-holes 13 are placed respectively on opposite or adjacent sides of the glass portions 2 or 3.

According to a further characteristic of the invention shown in FIG. 5, the photovoltaic glass bricks 1 can be combined such as to form a structure, for example a glass block wall 100 which acts as an electrical energy generator, or is directly connected to the electrical mains supply of the building, or in order to supply power to electronic devices of various kinds. In this case, as shown in this FIG. 5, the electrical energy produced by the glass block structure 100 is directed to a battery 16 on the exterior of this structure or wall, by means of an electrical connection 15. In the example shown, the glass block structure 100 is constituted by 12 photovoltaic glass bricks 1 connected electrically to one another in series by means of electrical connections 14.

Various users, or electrical or electronic devices, which can have various functions, can be connected to the battery 16. For example, by means of an electrical cable 17, the battery 16 is connected to a device (generically represented as 18) for movement of a curtain (not shown for the sake of simplicity), and/or a Wi-Fi repeater, and/or LED lights, or another type of lighting device, and/or to alarm devices (which for example are volumetric), and/or to a Hi-Fi repeater or other electrical devices, such as sensors of various kinds for example. All of these devices are positioned in the interior or on the exterior of the glass block structure itself. By means of a connection 19, an electrical socket and/or a USB socket 20 can also be connected to the battery 16.

It is also possible to use the glass bricks 1 individually or combined in a glass block element in order to supply power to said electronic devices directly, without needing to provide a battery.

A description has been provided of various embodiments of the present invention. It will be appreciated that other variants are possible, such as the one which includes more luminescent solar concentrators 4 inserted in the cavity 1A in the glass brick 1. These solutions also come within the scope of the invention as defined by the appended claims.

1. A glass brick comprising a body with two glass portions which are secured to one another, and define an inner cavity of this body, said portions defining two opposite free faces of said body, wherein, in the interior of said inner cavity a luminescent solar concentrator is inserted, said luminescent solar concentrator being perimetrically associated, on at least two sides, with a spacer unit which can accept the deformations of the luminescent solar concentrator when the luminescent solar concentrator receives solar radiation, and which unit can guarantee the stability of the positioning of said luminescent solar concentrator in the interior of the glass brick.

2. The glass brick according to claim 1, wherein the luminescent solar concentrator is connected to one of the two preformed portions of the glass brick.

3. The glass brick according to claim 2, wherein said luminescent solar concentrator is inserted in a recess which is present in an inner face of the portion of glass brick with which it is associated, said recess defining at least part of the inner cavity in the body of the glass brick.

4. The glass brick according to claim 1, wherein the luminescent solar concentrator is connected to an electrical circuit on the exterior of the glass brick.

5. The glass brick according to claim 4, wherein the luminescent solar concentrator comprises photovoltaic cells which can generate electrical energy from the solar radiation which strikes said luminescent solar concentrator, wherein said photovoltaic cells are connected to the exterior electrical circuit by means of an electrical cable which passes through a corresponding hole provided inside the body of said glass brick.

6. The glass brick according to claim 5, wherein said hole is provided in a side of a portion of the glass brick.

7. The glass brick according to claim 5, further comprising two holes which can contain corresponding electrical cables passing through the holes, said holes alternatively being provided in opposite sides or in adjacent sides of the body of the glass brick.

8. A glass block structure comprising a plurality of glass bricks according to claim 1, wherein the luminescent solar concentrators, and the photovoltaic cells of the luminescent solar concentrators are electrically connected to one another to collect the electrical energy produced by said plurality of glass bricks on the exterior of said glass structure.

9. The glass block structure according to claim 8, wherein it is connected to electrical and/or electronic devices comprising at least one from amongst actuator means placed at the glass block structure, electrochromic means, lights and/or alarm devices and/or sensor means or one or a plurality of electrical supply sockets, said connection to said electrical and/or electronic devices alternatively being obtained directly or by means of a battery which can accumulate the energy produced by the luminescent solar concentrators, and to which said electrical and/or electronic devices are connected directly.
